(19) United States
(12) Patent Application Publication
(10) Pub. No.: US 2026/0011590 A1
(43) Pub. Date: Jan. 8, 2026

(54) SUBSTRATE CONTAINER ADAPTER

(71) Applicant: ENTEGRIS, INC., Billerica, MA (US)

(72) Inventors: Jack Dunlope, Colorado Springs, CO (US); Matthew A. Fuller, Colorado Springs, CO (US); Christopher Strickhouser, Monument, CO (US); Curt A. Mulick, Colorado Springs, CO (US)

(21) Appl. No.: 19/260,128

(22) Filed: Jul. 3, 2025

Related U.S. Application Data
(60) Provisional application No. 63/667,671, filed on Jul. 3, 2024.

(51) Int. Cl. H01L 21/673

(52) U.S. Cl. CPC H01L 21/67386; H01L 21/67373; H01L 21/67393

(57) ABSTRACT

Apparatuses including substrate container attachment interfaces and substrate container adapters are provided. The substrate container attachment interfaces and substrate container adapters include at least one engagement feature configured to engage with a projection or recess provided in a substrate container. Adapters can include a cassette configured to be attached to, or integrally formed including the substrate container attachment interfaces. The substrate container attachment interfaces can attach to side columns provided in substrate containers. The substrate container attachment interfaces can include or be joined to environmental adjustment packs and/or sensors. The adapters can be configured to be at predetermined heights, and the predetermined heights can be selected based on interactions with automated handling.

### FIELD

This disclosure is directed to adapters for interfacing with substrate containers to allow inclusion of different modules and/or storage of different types of substrates, wafers, trays, panels, and the like.

### BACKGROUND

Substrate containers are typically sized for one size of substrate, such as, for example, 300 millimeter (mm) wafers. Adapters can be provided that can fit within the substrate container so as to accommodate a different size substrate, such as 200 mm wafers, however these adapters typically are not secured within the substrate container and can fall out during processes such as, for example, washing. Additionally, such adapters may not provide consistent enough indexing of height for the substrates to allow use with automation.

### SUMMARY

This disclosure is directed to adapters for interfacing with substrate containers to allow inclusion of different modules and/or storage of different types of substrates, wafers, trays, panels, and the like.

By attaching to side columns and other such internal features of the substrate container, interface apparatuses and adapters according to embodiments can increase the variety of items that can be contained within the substrate containers while still allowing for automated handling of the items. Additionally, the secure attachment provided by the substrate container interface in such apparatuses and adapters can allow the apparatuses and adapters to be used in substrate containers used in processes where the substrate containers are automatically washed. The substrate container can also facilitate the use of sensors, environment adjustment packs, and the like to facilitate environmental control and awareness of conditions within the substrate container. The adapters can additionally allow the substrate containers to be used in additional processes and integrate with automation used in such processes to handle the substrates, wafers, trays, panels, and the like.

In an embodiment, an article for a substrate container includes a substrate container interface apparatus. The substrate container interface apparatus has an engagement feature configured to engage with a projection or recess provided in a substrate container, so as to fix the substrate container interface apparatus to the substrate container within an internal space of the substrate container.

In an embodiment, the apparatus further includes an environmental adjustment pack connected to the substrate container interface apparatus. In an embodiment, the apparatus further includes a sensor connected to the substrate container interface apparatus.

In an embodiment, the engagement feature includes a spring and a contact surface disposed on said spring, the contact surface configured to engage a shelf provided on a side column of the substrate container. In an embodiment, the contact surface is configured to engage the shelf along a curved portion of said shelf. In an embodiment, the engagement feature includes a snap-fit feature configured to engage with a rear of the side column of the substrate container.

In an embodiment, an article for a substrate container includes a substrate container adapter. The substrate container adapter includes a substrate container interface including at least one engagement feature configured to engage with a projection or recess provided in a substrate container so as to fix the substrate container interface within an internal space of the substrate container and a cassette configured to accommodate one or more substrates, panels, and/or trays, the cassette configured to attach to the substrate container interface.

In an embodiment, the cassette is configured to accommodate at least one panel. In an embodiment, the cassette is configured to accommodate at least one substrate. In an embodiment, the cassette includes a locking member configured to restrict movement of the engagement feature when the cassette is joined to the interface.

In an embodiment, the article further includes a second substrate container interface, the second substrate container interface including an engagement feature configured to engage with a second projection or recess provided in the substrate container so as to fix the second substrate container interface to the substrate container.

In an embodiment, the substrate container interface is formed integrally with the cassette. In an embodiment, the substrate container interface is configured to provide the cassette at a predetermined height within the substrate container. In an embodiment, a substrate container includes a substrate container body. One or more projections or recesses are provided on at least one surface an internal space defined by the substrate container body. The substrate container further includes a substrate container interface apparatus. The substrate container interface apparatus includes at least one engagement feature configured to engage with at least one of the one or more projections or recesses so as to fix the substrate container interface apparatus to the substrate container within the internal space of the substrate container.

In an embodiment, the one or more projections or recesses include a side column provided in the substrate container body.

In an embodiment, the at least one engagement feature includes a spring configured to engage a shelf provided on the side column, along a curved portion of said shelf. In an embodiment, the substrate container interface apparatus includes a sensor or an environment adjustment pack.

In an embodiment, the substrate container further includes a cassette, the cassette configured to be attached to the substrate container interface apparatus, the cassette configured to accommodate at least one substrate, panel, or tray.

In an embodiment, the substrate container further includes a second substrate container interface apparatus comprising at least one second engagement feature configured to engage with at least one of the one or more projections or recesses so as to fix the second substrate container interface apparatus to the substrate container, wherein the cassette is further configured to be attached to the second substrate container interface apparatus, and wherein the substrate container interface apparatus and the second substrate container interface apparatus are configured to provide the cassette at a predetermine height within the substrate container. In an embodiment, the predetermined height is selected to position the cassette at a height for receiving the at least one substrate, panel, or tray from an automated handler.

### DRAWINGS

FIG. 1 shows an exploded view of a substrate container according to an embodiment.

FIG. 2 shows a substrate container interface adapter according to an embodiment.

FIG. 3 shows a substrate container interface adapter including a functional module according to an embodiment.

FIG. 4 shows a substrate container interface adapter joined to a side column of a substrate container according to an embodiment.

FIG. 5 shows a substrate container interface adapter joined to a side column of a substrate container according to an embodiment.

FIG. 6A shows an attachment feature for a substrate container interface adapter according to an embodiment.

FIG. 6B shows an attachment feature for a substrate container interface adapter according to an embodiment.

FIG. 6C shows an attachment feature for a substrate container interface adapter according to an embodiment.

FIG. 7A shows a substrate container and a substrate container interface adapter according to an embodiment.

FIG. 7B shows engagement of the substrate container interface adapter and the substrate container of FIG. 7A.

### DETAILED DESCRIPTION

This disclosure is directed to adapters for interfacing with substrate containers to allow inclusion of different modules and/or storage of different types of substrates, wafers, trays, panels, and the like.

As used herein, "substrate container" is a container configured to be capable of accommodating one or more substrates within an internal space defined by said container. The substrates can be, for example, wafers of a predetermined size, such as, as a non-limiting example, 300 millimeter (mm) wafers.

A non-limiting example of a substrate container is a front opening unified pod (FOUP) configured to contain 300 mm wafers. As used herein, "fix" means to attach securely, such that the components fixed to one another do not significantly move relative to one another. The attachment can be secure such that the attachment can resist forces applied to one or both of the components fixed to one another. An example of resisting forces and maintaining the attachment is remaining connected when gravitational force is acting on at least one of the components, such as an attachment interface remaining secured within a substrate container when the substrate container is positioned opening- downwards, for example during an automated washing process.

As used herein, "within" means "in an internal space defined by." The internal space can be defined inside of a container by one or more surfaces, such as the wafer containing space defined by walls of a substrate container. The internal space can include at least one open face, such as a door opening of a substrate container.

As used herein, "accommodate" means "being capable of entirely containing."

As used herein, "environmental adjustment pack" is a device, material, or a container that contains a device or material that is capable of affecting environmental conditions within a substrate container, for example a desiccant pack, a getter containing a material such as a desiccant, an adsorbent pack, a getter containing an adsorbent, a pack or getter containing a material to be diffused within the substrate container, combinations thereof, weights (for example, to affect center of gravity), or the like.

As used herein, "sensor" is an electronic sensor configured to detect or measure one of more environmental conditions within a substrate container, such as a temperature sensor, a humidity sensor, a chemical sensor configured to detect a presence and/or amount of one or more chemicals, or the like. In an embodiment, the sensor can be battery powered. In an embodiment, the sensor can be configured record data for subsequent retrieval. In an embodiment, the sensor can be configured to communicate measured data. In an embodiment, the sensor can be configured to communicate the measured data to a receiver while the substrate container is being used in a process. In an embodiment, the sensor can be configured to communicate the data being obtained by said sensor in real time.

As used herein, "panel" is a generally rectangular substrate used in chip manufacturing, typically as a foundation for the formation of the chip.

As used herein, "tray" is a planar structure configured to support one or more substrates, wafers, diced chips, reticle, or any other component used in or resulting from semiconductor production. The tray is not integral with the structure of the substrates, wafers, diced chips, reticle, or the like supported thereby. In an embodiment, the tray can be sized and/or shaped according to an applicable standard, such as standards promulgated by the Joint Electron Device Engineering Council (JEDEC).

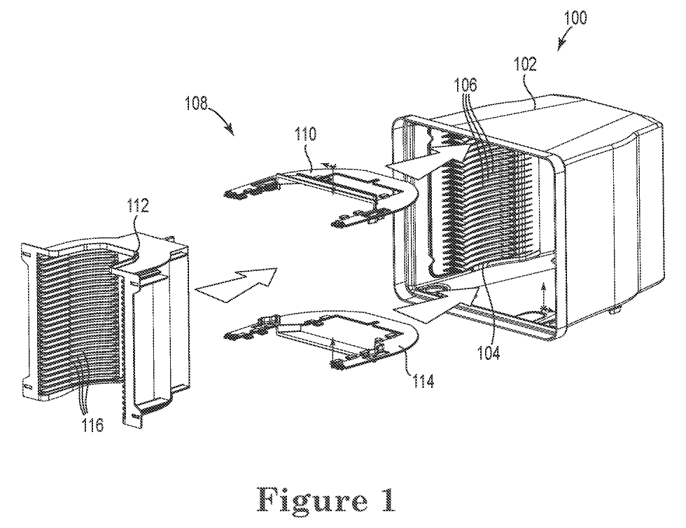

FIG. 1 shows an exploded view of a substrate container according to an embodiment. Substrate container 100 includes substrate container body 102. Substrate container body 102 includes side columns 104 including support shelves 106. The substrate container 100 further includes an adapter 108. The adapter 108 includes a first substrate container interface 110, a cassette 112, and a second substrate container interface 114. Cassette 112 includes second support shelves 116.

Substrate container 100 is a container configured to accommodate one or more one or more substrates, panels, trays, or combinations thereof in cassette 112. Substrate container body 102 defines an internal space. Substrate container body 102 can be, for example, the body of a substrate container configured to accommodate a particular size and/or type of substrate. A non-limiting example of a substrate container body 102 can be a body of a front-opening unified pod (FOUP) configured to accommodate 300 millimeter (mm) wafers. Substrate container body 102 can include one or more components. In an embodiment, substrate container body 102 is configured to receive a door (not shown) to enclose the internal space define within the substrate container body.

Side columns 104 define a plurality of the support shelves 106, configured to support substrates that the substrate container body 102 is configured to accommodate. In an embodiment, the side columns 104 can be formed integrally with the substrate container body 102. In an embodiment, the side columns 104 can be separate components that are fixed within the substrate container body 102, for example by mechanical engagement of suitable features such as slots, tabs, projections, recesses, snap-fit features, combinations thereof, and the like. The side columns 104 can include a curved and/or angled region along the side walls of one or more of the projections defining shelves. In an embodiment, for example where the side columns 104 are separate from the substrate container body, the side columns 104 can include a flat surface at an end of said side column 104 towards a rear wall of the substrate container body 102.

Support shelves 106 are defined by the side columns 104. The support shelves 106 are configured to support the substrates that the substrate container body 102 is configured to accommodate, for example 300 mm wafers. The support shelves 106 can include a curved or angled surface along side walls thereof.

Adapter 108 is an adapter configured to allow the substrate container body 102 to be used to contain one or more one or more substrates, panels, trays, reticles, or combinations thereof other than the substrates that the substrate container body 102 is ordinarily configured to accommodate. As a non-limiting example, where substrate container body 102 is a body of a FOUP configured for 300 mm wafers, the adapter 108 can be configured to support 200 mm wafers.

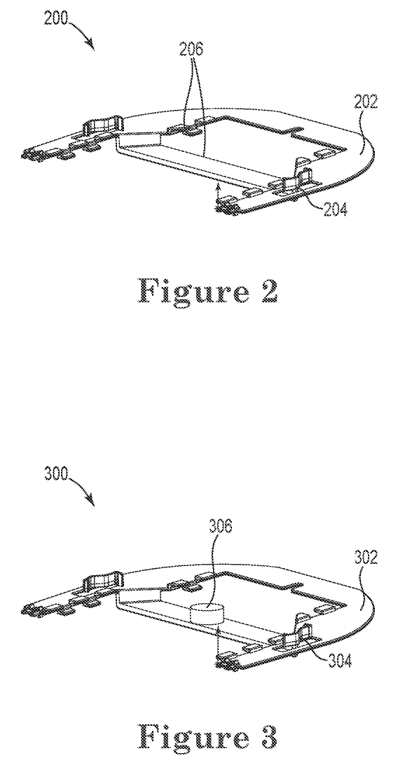

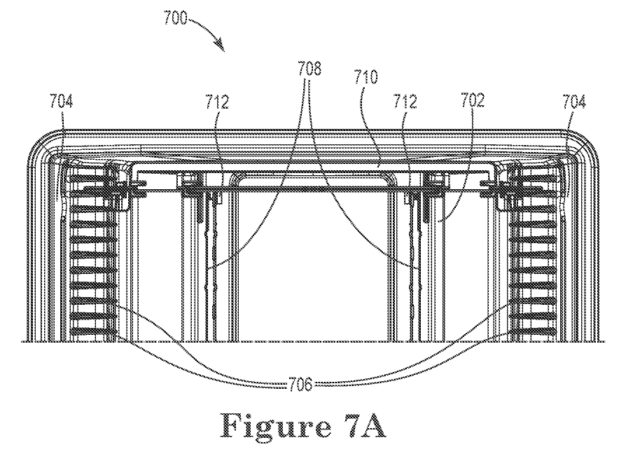

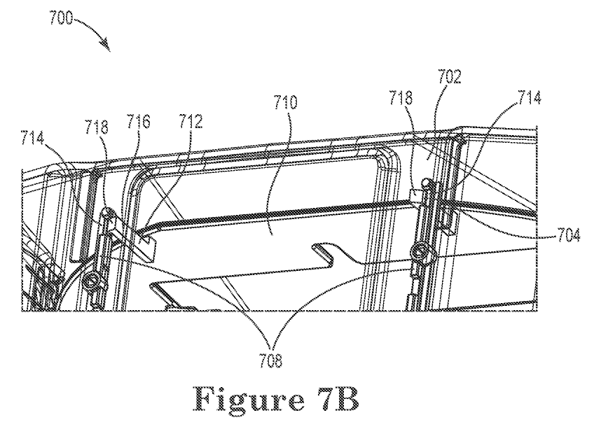

First substrate container interface 110 is configured to attach to the side columns 104 of the substrate container 100. The first substrate container interface can include an outer portion configured to be received in the support shelves 106, and an engagement feature configured to engage with the side columns 104. Examples of the engagement of the engagement feature with the side column can include engagement with curved or angled portions of the support shelves 106, engagement with ends of the side columns 104, or the like. Examples of the engagement features are described below and shown in detail in .FIGS. 2-6C In an alternative embodiment, the engagement feature of a first substrate container interface 110 can engage with a rail feature formed in the substrate container body 102, for example as shown in FIG. 7A-B and described below.

Cassette 112 is configured to be attached to first substrate container interface 110. The cassette is configured to at least partially define an internal space. The cassette 112 is configured to be accommodated within the internal space of substrate container body 102. The internal space defined by cassette 112 can configured to contain one or more one or more substrates, panels, trays, reticles, or combinations thereof other than the substrates that the substrate container body 102 is ordinarily configured to accommodate. In the non-limiting example discussed above for adapter 108, the cassette 112 can be configured to accommodate the 200 mm wafers. The cassette 112 can include any suitable shelves, support posts, or any other suitable feature to support the particular contents of said cassette 112. One example of such support features is the second support shelves 116 as shown in FIG. 1 and described further below. The cassette 112 is further configured to engage with at least first substrate container interface 110 and optionally also with second substrate container interface 114 such that the cassette 112 can be secured within the substrate container body 102. In an embodiment, the cassette 112 is configured such that the one or more one or more substrates, panels, trays, or reticles are supported in predetermined positions selected for automation to interface with said one or more one or more substrates, panels, trays, or reticles. For example, the cassette 112 can present wafers at heights within the substrate container body 102 defined according to a standard, such as a coordinate system, used in the interactions of automation with the contents of the substrate container 100.

In an embodiment, the cassette 112 and one or both of first and second substrate container interfaces 110, 114 can be formed integrally. In an embodiment, the cassette 112 can be attached to one or both of the first and second substrate container interfaces 110, 114 by any suitable connection, such as one or more mechanical interfaces, fasteners, combinations thereof, and the like. The mechanical interfaces can be any suitable mechanical interfaces, such as one or more snap-fits formed by corresponding features, corresponding projections, recesses, slots, tabs, and/or grooves, and the like. The fasteners can be, for example, screws, snaps, pins, or any other such suitable fasteners.

Optionally, a second substrate container interface 114 can be provided, for example to further support cassette 112. For example, second substrate container interface 114 can In an embodiment, the second substrate container interface 114 can be identical to or a mirror image of the first substrate container interface 110. The second substrate container interface 114 can be configured to be attached to the substrate container body 102, for example at side columns 104 or the like, at a different point from first substrate container interface 110.

For example, the second substrate container interface 114 can attach to side columns 104 at different support shelves 106 from those engaged by first substrate container interface 110. The second substrate container interface 114 can include any suitable features for the attachment to the side columns 104 and/or other suitable features of the substrate container body 102 as discussed above regarding first substrate container interface 110. In an embodiment, the second substrate container interface 114 includes engagement features identical to those included in first substrate container interface 110. In an embodiment, the second substrate container 114 includes different engagement features from those of the first substrate container interface 110. Second support shelves 116 can be provided within cassette 112. The second support shelves can be one or more pairs of opposing shelves configured to support any suitable contents of the cassette 112, with non-limiting examples being one or more substrates, panels, trays, reticles, or combinations thereof. The contents of the cassette can be smaller than a size of substrate that substrate container body 102 is configured to accommodate.

FIG. 2 shows a substrate container interface adapter according to an embodiment. Substrate container interface adapter 200 includes interface body 202 and engagement feature 204. The substrate container interface adapter 200 further includes a cassette interface feature 206.

Substrate container interface adapter 200 is configured to engage with a body of a substrate container, such as the substrate container body 102 described above and shown in, Fig. 1 such that the substrate container interface adapter 200 is fixed within said body of the substrate container. Substrate container interface adapter 200 can be configured to support a cassette within the body of the substrate container. Substrate container interface adapter 200 has interface body 202. Interface body 202 can be made of any suitable material, such as a polymer. Non-limiting examples of suitable polymers include a polyolefin, a polycarbonate, or the like. The interface body 202 can be configured to extend within the body of the substrate container, for example from one side column of the substrate container body to an opposing side column. In an embodiment, interface body 202 can be shaped and sized, for example having a surface area, a thickness, combinations thereof, or the like selected to provide sufficient rigidity to support the cassette at a suitable height within the substrate container. In an embodiment, the interface body 202 can be shaped or sized such that a pair of the substrate interface adapters 200 can support the cassette. In an embodiment, at least a portion of the interface body 202 can be configured to be received in a wafer slot defined by the side column provided in the substrate container body.

Engagement feature 204 is a feature configured to engage the substrate container body so as to fix the substrate container interface adapter 200 within the substrate container body. The engagement feature 204 can be configured to engage the substrate container body at any suitable location or plurality of locations, for example at side columns or portions thereof such as shelves, a rear of the side columns, or the like, or at a rail interface formed within the substrate container body. Non-limiting examples of engagement features are shown in and described in detail below. Engagement feature 204 can be configured such that when the substrate container body is positioned with an opening facing downwards, for example during a washing process of the substrate container, the substrate container interface adapter remains fixed within said substrate container body. In an embodiment, the engagement feature 204 can include a spring and an engagement surface.

Cassette interface feature 206 is configured to allow a cassette to be attached to the substrate container interface 200. Cassette interface feature 206 can include any suitable features for mechanical engagement with the cassette. In an embodiment, cassette interface feature 206 can include one or more tabs configured to interface with a portion of the cassette. In an embodiment, the cassette interface feature can include a support brace configured to contact the cassette. In an embodiment, a support brace can be included in combination with another mechanical engagement feature such as the one or more tabs discussed above. In an embodiment, the cassette interface feature 206 is tuned to provide the cassette at a predetermined height within the body of the substrate container, such that contents of the cassette are at suitable heights for interaction with automation. For example, the cassette interface feature can be configured such that the cassette is retained in a position where the contents of the cassette are presented at predetermined positions according to a coordinate system within the substrate container. In an embodiment, the coordinate system used can be a standard coordinate system for interfacing of automation with the substrate container.

FIG. 3 shows a substrate container interface adapter including a functional module according to an embodiment. Substrate container interface adapter 300 includes interface body 302 and engagement feature 304. The substrate container interface adapter 300 further includes a functional module 306.

Substrate container interface adapter 300 is configured to engage with a body of a substrate container, such as the substrate container body 102 described above and shown in FIG. 1, such that the substrate container interface adapter 300 is fixed within said body of the substrate container. Substrate container interface adapter 300 can be configured to support a cassette within the body of the substrate container. Substrate container interface adapter 300 has interface body 302. Interface body 302 can be made of any suitable material, such as a polymer. Non-limiting examples of suitable polymers include a polyolefin, a polycarbonate, or the like. The interface body 302 can be configured to extend within the body of the substrate container, for example from one side column of the substrate container body to an opposing side column. In an embodiment, interface body 302 can be shaped and sized, for example having a surface area, a thickness, combinations thereof, or the like selected to provide sufficient rigidity to support the cassette at a suitable height within the substrate container.

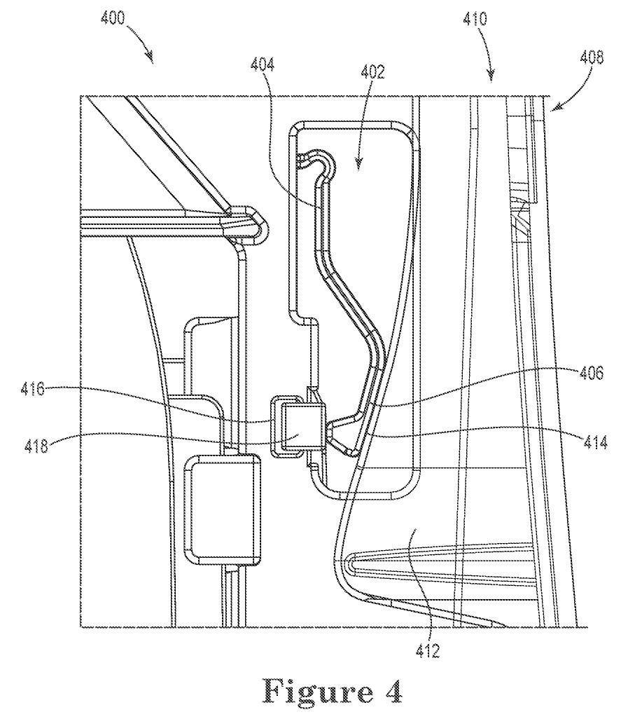

In an embodiment, the interface body 302 can be shaped or sized such that a pair of the substrate interface adapters 300 can support the cassette. In an embodiment, at least a portion of the interface body 302 can be configured to be received in a wafer slot defined by the side column provided in the substrate container body. Engagement feature 304 is a feature configured to engage the substrate container body so as to fix the substrate container interface adapter 300 within the substrate container body. The engagement feature 304 can be configured to engage the substrate container body at any suitable location or plurality of locations, for example at side columns or portions thereof such as shelves, a rear of the side columns, or the like, or at a rail interface formed within the substrate container body. Non-limiting examples of engagement features are shown in FIGS. 4-6c and described in detail below. Engagement feature 304 can be configured such that when the substrate container body is positioned with an opening facing downwards, for example during a washing process of the substrate container, the substrate container interface adapter remains fixed within said substrate container body. In an embodiment, the engagement feature 304 can include a spring and an engagement surface.

Functional module 306 is included in or attached to interface body 302. Functional module 306 is configured to provide a desired sensing and/or environmental adjustment function for the internal space defined by the substrate container body. Functional module 306 can include one or more sensors and/or one or more environmental adjustment packs. In an embodiment, the sensor(s) can be one or more electronic sensors configured to detect or measure one of more environmental conditions within a substrate container. Non-limiting examples of sensors that can be included in functional module 306 include a temperature sensor, a humidity sensor, a chemical sensor configured to detect a presence and/or amount of one or more chemicals, or the like. In an embodiment, the sensor can be battery powered. In an embodiment, the sensor can be configured record data for subsequent retrieval. In an embodiment, the sensor can be configured to communicate measured data. In an embodiment, the sensor can be configured to communicate the measured data to a receiver while the substrate container is being used in a process. In an embodiment, the sensor can be configured to communicate the data being obtained by said sensor in real time. In an embodiment, the environmental adjustment pack can be a device, material, or a container that contains a device or material that is capable of affecting environmental conditions within a substrate container. Non-limiting examples of environmental adjustment packs that can be used as or in functional module 306 can include a desiccant pack, a getter containing a material such as a desiccant, an adsorbent pack, a getter containing an adsorbent, a pack or getter containing a material to be diffused within the substrate container, combinations thereof, or the like.

FIG . 4 shows a substrate container interface adapter joined to a side column of a substrate container according to an embodiment. Substrate container interface adapter 400 includes attachment feature 402. Attachment feature 402 includes a spring arm 404 and a contact surface 406. Substrate container 408 includes side column 410, which includes substrate support shelf 412. The substrate support shelf 412 can have a contact region 414.

Attachment feature 402 extends into an opening formed within the substrate container interface adapter 400. The attachment feature 402 can extend beyond a thickness of the substrate container interface adapter 400 surrounding said opening, for example such that a portion outside the opening can be rest on substrate support shelf 412 or an adjacent substrate support shelf while the attachment feature 402 contacts the support shelf 412 at contact region 414.

Spring arm 404 extends into the opening formed in the substrate container interface adapter 400. The spring arm 404 is configured to be deflected such that contact surface 406 can move into a position where the substrate container interface adapter 400 can be inserted into the substrate container 408 without interference between the contact surface 406 and the support shelf 412 preventing such insertion. The spring arm 404 can be configured to restore the contact surface position 406 once the contact surface 406 has passed a portion of the contact region 414, such that the contact surface 406 contacts the contact region 414 so as to retain a position of the substrate container interface adapter 400.

Contact surface 406 is a surface configured to engage with the contact region 414 to retain a position of the substrate container interface adapter 400 along a direction parallel to a major axis of the support shelf 412. Contact surface 406 is disposed along or at an end of the spring arm 404. The contact surface 406 can have a shape corresponding to a shape of at least a portion of contact region 414, such as being planar, concave, or convex.

Substrate container 408 is a substrate container such as, as a non-limiting example, a FOUP. Substrate container 408 defines an internal space. The internal space can be defined by top, bottom, rear, and opposing side walls of substrate container 408. The substrate container 408 can include an opening opposite the rear wall, configured to receive a door so as to enclose the internal space of substrate container 408.

The substrate container 408 can be configured to receive a particular type of substrate, with a non-limiting example being a 300 mm wafer. The substrate container 408 includes side columns 410. Side columns 410 can be provided at or near side walls defining the internal space of the substrate container 408. In an embodiment, the side columns 410 can be formed integrally with a body of the substrate container 408. In an embodiment, the side columns 410 can be separate elements from the body of substrate container 408 that are mechanically fixed within the internal space of the substrate container 408, for example through snap-fit features, fasteners, or any other suitable mechanical connection. The side columns 410 can include one or more substrate support shelves 412. The substrate support shelf 412 is configured to receive and support one of the substrates that the substrate container 408 is configured to receive, such as the 300 mm wafer discussed above. In an embodiment, the substrate support shelf can extend along the side column 410 in a direction parallel to a direction from a rear wall of the substrate container 408 towards the door opening. In an embodiment, the substrate support shelf 412 projects inwards into the internal space of the substrate container 408 in a direction from one of the side walls towards an opposing side wall of the substrate container 408.

Contact region 414 is a portion of the substrate support shelf 412 where contact surface 406 can engage the substrate support shelf 412 such that movement of the substrate container interface adapter 400 along the extending direction of substrate support shelf 412 is restricted or prevented. Contact region 412 can be along a side of the substrate support shelf 412. In an embodiment, contact region 414 can be a portion of the substrate support shelf 412 where there is variance in the extent the substrate support shelf projects inwards into the substrate container including the side column 410. The contact region 414 can be straight, concave, convex, or combinations thereof over the length of the contact region 414.

Optionally, in an embodiment, the substrate container interface adapter 400 can have a locking feature aperture 416. Locking aperture 416 can be an opening formed between a body of the substrate container interface adapter 400 and the spring arm 404 when the spring arm 404 is in position to secure the substrate container interface adapter 400 to the contact region 414 of the substrate support shelf 412. The locking aperture is configured to receive a locking feature 418. The locking feature 418 can be configured to obstruct deflection of the spring arm 404 such that the spring arm cannot move to a position allowing the substrate container interface adapter 400 to be removed from substrate container 408. In an embodiment, the locking feature 418 can be provided on a cassette configured to be used with the substrate container interface adapter 400. In such an embodiment, the locking feature can be configured to be inserted into locking aperture 416 when the cassette is joined to the substrate container interface adapter 400. In an embodiment, the locking feature 418 can be provided on a functional module, such as functional module 306 described above and shown in,Fig.3 configured to be attached to the substrate container interface adapter 400. In an embodiment, the locking feature 418 can be a discrete element separate from the substrate container interface adapter 400 and any cassette or functional module to be used therewith.

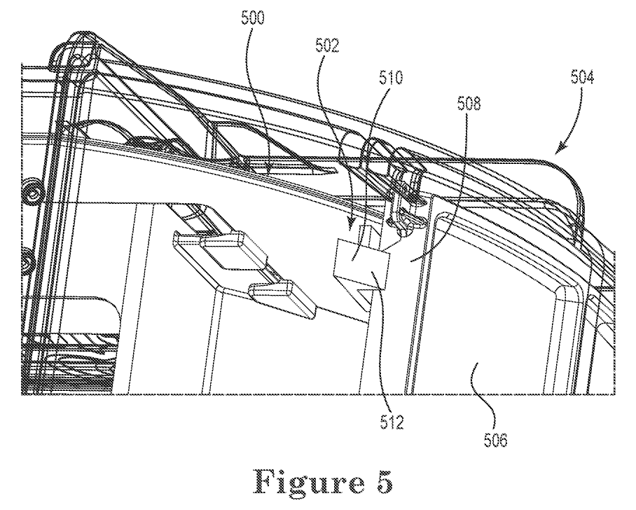

FIG. 5 shows a substrate container interface adapter joined to a side column of a substrate container according to an embodiment. Substrate container interface adapter 500 includes attachment feature 502. Substrate container 504 includes side column 506. In the embodiment shown in FIG. 5, the attachment feature 502 is a snap-fit feature configured to snap over a rear side 508 of the side column 506. The attachment feature 502 can include a sliding surface 510 and a retention feature 512. The sliding surface 510 can be an angled surface configured to be slid over the side column 506, deflecting the attachment feature 502 as the sliding surface passes over the rear side 508 of side column 506. The attachment feature can snap to the side column 506 such that retention feature 512 can contact the rear side 508 of the side column 506. The contact between retention feature 512 and rear side 508 can be such that the substrate container interface adapter 500 is secured to the side column 506. The attachment feature 502 can be used, for example, with side columns 506 that are not integral with the substrate container body that substrate interface adapter 500 is configured to be installed into.

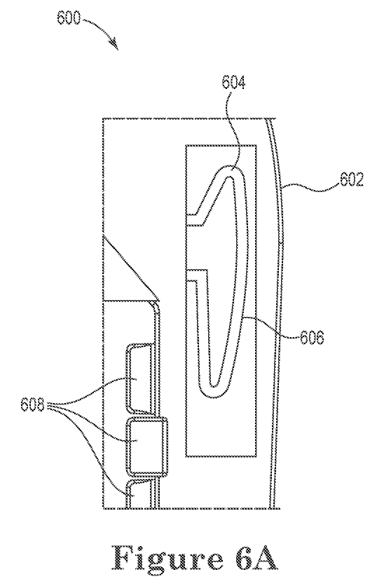

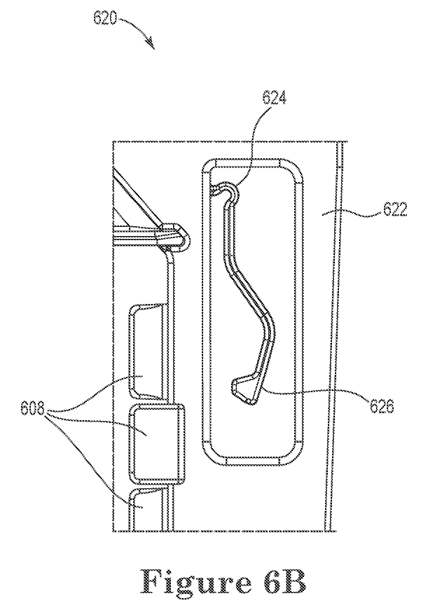

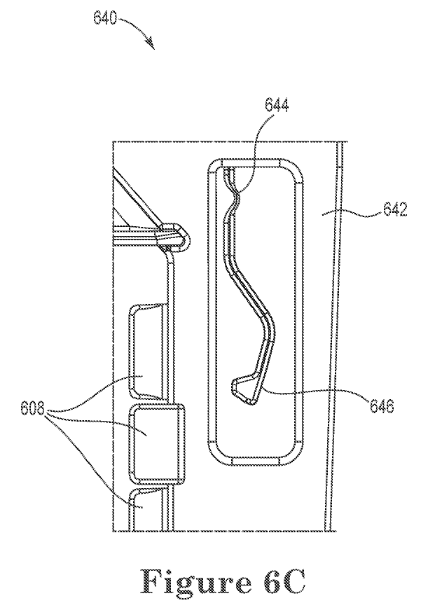

FIG. 6A shows an attachment feature for a substrate container interface adapter according to an embodiment. Substrate container interface adapter 600 includes outer portion 602 and spring member 604. In the embodiment shown in FIG. 6A, spring member 604 is a continuous loop of material, with curved surface 606 configured to engage with a curved side edge of a shelf provided on a side column of a wafer container so as to retain the substrate container interface adapter 600 along a direction in plane with the shelf. The spring member 604 is sized, shaped, and/or the material selected such that spring member 604 can deflect to allow insertion of the substrate container interface adapter 600 into the substrate container. The spring member 604 can further be configured such that said spring member 604 can deflect under sufficient force to allow removal of the substrate container interface adapter 600 from the substrate container. The outer portion 602 can be configured to contact at least one shelf on an upper or lower surface so as to retain the substrate container interface adapter 600 in a predetermined vertical position within the substrate container.

At least portions of the spring member 604 can extend vertically above and/or below outer portion 602 such that the outer portion 602 can contact upper and/or lower surfaces of one or more shelves while the spring member 604 engages a side of at least one shelf. Cassette engagement feature 608 can be seen opposite the outer portion 602 as shown in FIG. 6B. The cassette engagement feature 608 is an optional feature of the substrate container interface adapter 600 configured allow a cassette to be mechanically attached to the substrate container interface adapter 600, for example through interface with corresponding engagement features provided on the cassette. The cassette engagement feature 608 can be any suitable one or more engagement features for a forming at least a portion of a mechanical connection, such as one or more tabs, slots, snap-fit features, or the like. The features shown in can also be provided on an opposite side of the substrate container interface adapter 600 from the portion shown in , FIG. 6B such that the substrate container interface adapter 600 engages each of opposing sets of shelves provided on opposing side columns of the substrate container.

FIG. 6B shows an attachment feature for a substrate container interface adapter according to an embodiment. Substrate container interface adapter 620 includes outer portion 622, spring arm 624, and contact surface 626. The outer portion 622 can be configured to contact at least one shelf on an upper or lower surface so as to retain the substrate container interface adapter 620 in a predetermined vertical position within the substrate container. At least portions of the contact surface 626 and optionally the spring arm 624 can extend vertically above and/or below outer portion 622 such that the outer portion 622 can contact upper and/or lower surfaces of one or more shelves while the contact surface 626 engages a side of at least one shelf. Spring arm624 is configured to allow deflection such that the spring arm 624 and contact surface 626 can pass over the side wall of the shelf when substrate container interface adapter 620 is inserted into the substrate container. In the embodiment shown in FIG. 6B, the spring arm 624 includes a bend. The bend can be of any particular angle based on where the spring arm 620 connects to the body of the substrate container interface adapter, such as, as a non-limiting example, the approximately 90 degree bend shown in FIG. 6B. The contact surface 626 can be configured to contact the side wall of the shelf such that the substrate container interface adapter 600 is retained in position within the substrate container, with the spring arm 624 providing force to allow the contact surface to retain the position of the substrate container interface adapter 620. Cassette engagement feature 628 can be seen opposite the outer portion 622 as shown in FIG. 6B. The cassette engagement feature 628 is an optional feature of the substrate container interface adapter 620 configured allow a cassette to be mechanically attached to the substrate container interface adapter 620, for example through interface with corresponding engagement features provided on the cassette. The cassette engagement feature 628 can be any suitable one or more engagement features for a forming at least a portion of a mechanical connection, such as one or more tabs, slots, snap-fit features, or the like. The features shown in FIG. 6B can also be provided on an opposite side of the substrate container interface adapter 620 from the portion shown in FIG. 6B, such that the substrate container interface adapter 620 engages each of opposing sets of shelves provided on opposing side columns of the substrate container.

FIG. 6C shows an attachment feature for a substrate container interface adapter according to an embodiment. FIG. 6C shows an attachment feature for a substrate container interface adapter according to an embodiment. Substrate container interface adapter 640 includes outer portion 642, spring arm 644, and contact surface 646. The outer portion 642 can be configured to contact at least one shelf on an upper or lower surface so as to retain the substrate container interface adapter 640 in a predetermined vertical position within the substrate container. At least portions of the contact surface 646 and optionally the spring arm 644 can extend vertically above and/or below outer portion 642 such that the outer portion 642 can contact upper and/or lower surfaces of one or more shelves while the contact surface 646 engages a side of at least one shelf. Spring arm 644 is configured to allow deflection such that the spring arm 644 and contact surface 646 can pass over the side wall of the shelf when substrate container interface adapter 640 is inserted into the substrate container. In the embodiment shown in FIG. 6C, the spring arm 644 includes a bent portion, but continues in generally the same direction following the bent portion. The extending direction following the bent portion any particular angle based on where the spring arm 640 connects to the body of the substrate container interface adapter. The contact surface 646 can be configured to contact the side wall of the shelf such that the substrate container interface adapter 600 is retained in position within the substrate container, with the spring arm 644 providing force to allow the contact surface to retain the position of the substrate container interface adapter 640. Cassette engagement feature 648 can be seen opposite the outer portion 642 as shown in FIG. 6B. The cassette engagement feature 648 is an optional feature of the substrate container interface adapter 640 configured allow a cassette to be mechanically attached to the substrate container interface adapter 640, for example through interface with corresponding engagement features provided on the cassette. The cassette engagement feature 648 can be any suitable one or more engagement features for a forming at least a portion of a mechanical connection, such as one or more tabs, slots, snap-fit features, or the like. The features shown in FIG. 6B can also be provided on an opposite side of the substrate container interface adapter 640 from the portion shown in FIG. 6B, such that the substrate container interface adapter 640 engages each of opposing sets of shelves provided on opposing side columns of the substrate container.

FIG. 7A shows a substrate container and a substrate container interface adapter according to an embodiment. Substrate container 700 includes a back wall 702 opposite an open end of the substrate container 700. The substrate container 700 includes opposing side walls 704 and substrate support shelves 706. The substrate container 700 includes rails 708 provided on the back wall 702. Rails 708 can be attached to back wall by any suitable connection, such as a mechanical connection, suitable engagement features, fasteners, combinations thereof, or the like. Rails 708 can include portions spaced apart from the back wall. Substrate container interface adapter 710 is configured to be inserted into the substrate container 700. Substrate container interface adapter 710 is configured to be received in substrate support shelves 706. Substrate container interface adapter 710 includes attachment features 712. Attachment features 712 are configured to engage with the rails 708. FIG. 7B shows engagement of the substrate container interface adapter and the substrate container of FIG. 7A. As can be seen in FIG. 7B, the rails 708 include engagement regions 714 where the rail is spaced apart from the back wall 702. The attachment features 712 can include a deflectable arm 716, a sloping surface 718, and an engagement surface 720. When substrate container interface adapter 710 is inserted into substrate container 700, the sloping surface 718 contacts a corresponding rail 708, deflecting deflectable arm 716. When the sloping surface 718 passes over the side of rail 708, the deflectable arm 716 returns to a resting position, positioning engagement surface 720 on engagement region 714, thus fixing the substrate container interface adapter 710 within substrate container 700. The substrate container interface adapter 710 can be removed by deflecting the deflectable arms 716 such that the engagement surfaces 720 can pass the sides of rails 708 to release the attachment features 712 from the rail 708.

Aspects: It is understood that any of aspects 1-6 can be combined with any of aspects 7-13 or 14- 20. In an embodiment, any of aspects 7-13 can be combined with any of aspects 14-20.

Aspect 1. An article for a substrate container, comprising a substrate container interface apparatus, having an engagement feature configured to engage with a projection or recess provided in a substrate container, so as to fix the substrate container interface apparatus to the substrate container within an internal space of the substrate container.

Aspect 2. The article according to aspect 1, further comprising an environmental adjustment pack connected to the substrate container interface apparatus.

Aspect 3. The article according to any of aspects 1-2, further comprising a sensor connected to the substrate container interface apparatus.

Aspect 4. The article according to any of aspects 1-3, wherein the engagement feature includes a spring and a contact surface disposed on said spring, the contact surface configured to engage a shelf provided on a side column of the substrate container.

Aspect 5. The substrate container interface apparatus according to aspect 4, wherein the contact surface is configured to engage the shelf along a curved portion of said shelf.

Aspect 6. The substrate container interface apparatus according to aspect 5, wherein the engagement feature includes a snap-fit feature configured to engage with a rear of the side column of the substrate container.

Aspect 7. An article for a substrate container, comprising a substrate container adapter, having: a substrate container interface including at least one engagement feature configured to engage with a projection or recess provided in a substrate container so as to fix the substrate container interface within an internal space of the substrate container; and a cassette configured to accommodate one or more substrates, panels, and/or trays, the cassette configured to attach to the substrate container interface.

Aspect 8. The article according to aspect 7, wherein the cassette is configured to accommodate at least one panel.

Aspect 9. The article according to any of aspects 7-8, wherein the cassette is configured to accommodate at least one substrate.

Aspect 10. The article according to any of aspects 7-9, wherein the cassette includes a locking member configured to restrict movement of the engagement feature when the cassette is joined to the interface.

Aspect 11. The article according to any of aspects 7-10, further comprising a second substrate container interface, the second substrate container interface including an engagement feature configured to engage with a second projection or recess provided in the substrate container so as to fix the second substrate container interface to the substrate container.

Aspect 12. The article according to any of aspects 7-11, wherein the substrate container interface is formed integrally with the cassette.

Aspect 13. The article according to any of aspects 7-12, wherein the substrate container interface is configured to provide the cassette at a predetermined height within the substrate container.

Aspect 14. A substrate container, comprising: a substrate container body, wherein one or more projections or recesses are provided on at least one surface an internal space defined by the substrate container body; a substrate container interface apparatus, the substrate container interface apparatus comprising at least one engagement feature configured to engage with at least one of the one or more projections or recesses so as to fix the substrate container interface apparatus to the substrate container within the internal space of the substrate container.

Aspect 15. The substrate container according to aspect 14, wherein the one or more projections or recesses include a side column provided in the substrate container body.

Aspect 16. The substrate container according to aspect 15, wherein the at least one engagement feature includes a spring configured to engage a shelf provided on the side column, along a curved portion of said shelf.

Aspect 17. The substrate container according to any of aspects 14-16, wherein the substrate container interface apparatus includes a sensor or an environment adjustment pack.

Aspect 18. The substrate container according to any of aspects 14-17, further comprising a cassette, the cassette configured to be attached to the substrate container interface apparatus, the cassette configured to accommodate at least one substrate, panel, or tray.

Aspect 19. The substrate container according to aspect 18, further comprising a second substrate container interface apparatus comprising at least one second engagement feature configured to engage with at least one of the one or more projections or recesses so as to fix the second substrate container interface apparatus to the substrate container, wherein the cassette is further configured to be attached to the second substrate container interface apparatus, and wherein the substrate container interface apparatus and the second substrate container interface apparatus are configured to provide the cassette at a predetermine height within the substrate container.

Aspect 20. The substrate container according to aspect 19, wherein the predetermined height is selected to position the cassette at a height for receiving the at least one substrate, panel, or tray from an automated handler.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. An article for a substrate container, comprising a substrate container interface apparatus,
having an engagement feature configured to engage with a projection or recess provided in a substrate container, so as to fix the substrate container interface apparatus to the substrate container within an internal space of the substrate container.

2. The article of claim 1, further comprising an environmental adjustment pack connected to the substrate container interface apparatus.

3. The article of claim 1, further comprising a sensor connected to the substrate container interface apparatus.

4. The article of claim 1, wherein the engagement feature includes a spring and a contact surface disposed on said spring, the contact surface configured to engage a shelf provided on a side column of the substrate container.

5. The substrate container interface apparatus of claim 4, wherein the contact surface is configured to engage the shelf along a curved portion of said shelf.

6. The substrate container interface apparatus of claim 5, wherein the engagement feature includes a snap-fit feature configured to engage with a rear of the side column of the substrate container.

7. An article for a substrate container, comprising a substrate container adapter, having:a substrate container interface including at least one engagement feature configured to engage with a projection or recess provided in a substrate container so as to fix the substrate container interface within an internal space of the substrate container; anda cassette configured to accommodate one or more substrates, panels, and/or trays, the cassette configured to attach to the substrate container interface.

8. The article of claim 7, wherein the cassette is configured to accommodate at least one panel.

9. The article of claim 7, wherein the cassette is configured to accommodate at least one substrate.

10. The article of claim 7, wherein the cassette includes a locking member configured to restrict movement of the engagement feature when the cassette is joined to the interface.

11. The article of claim 7, further comprising a second substrate container interface, the second substrate container interface including an engagement feature configured to engage with a second projection or recess provided in the substrate container so as to fix the second substrate container interface to the substrate container.

12. The article of claim 7, wherein the substrate container interface is formed integrally with the cassette.

13. The article of claim 7, wherein the substrate container interface is configured to provide the cassette at a predetermined height within the substrate container.

14. A substrate container, comprising:a substrate container body, wherein one or more projections or recesses are provided on at least one surface an internal space defined by the substrate container body;a substrate container interface apparatus, the substrate container interface apparatus comprising at least one engagement feature configured to engage with at least one of the one or more projections or recesses so as to fix the substrate container interface apparatus to the substrate container within the internal space of the substrate container.

15. The substrate container of claim 14, wherein the one or more projections or recesses include a side column provided in the substrate container body.

16. The substrate container of claim 15, wherein the at least one engagement feature includes a spring configured to engage a shelf provided on the side column, along a curved portion of said shelf.

17. The substrate container of claim 14, wherein the substrate container interface apparatus includes a sensor or an environment adjustment pack.

18. The substrate container of claim 14, further comprising a cassette, the cassette configured to be attached to the substrate container interface apparatus, the cassette configured to accommodate at least one substrate, panel, or tray.

19. The substrate container of claim 18, further comprising a second substrate container interface apparatus comprising at least one second engagement feature configured to engage with at least one of the one or more projections or recesses so as to fix the second substrate container interface apparatus to the substrate container, wherein the cassette is further configured to be attached to the second substrate container interface apparatus, and wherein the substrate container interface apparatus and the second substrate container interface apparatus are configured to provide the cassette at a predetermine height within the substrate container.

20. The substrate container of claim 19, wherein the predetermined height is selected to position the cassette at a height for receiving the at least one substrate, panel, or tray from an automated handler.
